(19) United States
(12) Patent Application Publication
(10) Pub. No.: US 2018/0149111 A1
(43) Pub. Date: May 31, 2018

(54) HEAT EXCHANGER FOR A MOTOR VEHICLE

(71) Applicant: Mahle International GmbH, Stuttgart (DE)

(72) Inventors: Fahmi Ben Ahmed, Stuttgart (DE); Matthias Ganz, Stuttgart (DE); Klaus Luz, Herrenberg (DE); Holger Schroth, Maulbronn (DE)

(21) Appl. No.: 15/825,063

(22) Filed: Nov. 28, 2017

(30) Foreign Application Priority Data
Nov. 29, 2016 (DE) 10 2016 008 276.1
Nov. 29, 2016 (DE) 20 2016 008 278.8
Jun. 20, 2017 (DE) 10 2017 210 271.3

(51) Int. Cl. F02G 5/02; F01N 3/02; F01N 5/02; H01L 35/30; F01N 1/16

(52) U.S. Cl. CPC F02G 5/02; F01N 3/0205; F01N 5/025; H01L 35/30; F01N 2470/00; F01N 2240/36; F01N 2240/02; F01N 2240/04; F01N 1/165

(57) ABSTRACT

A heat exchanger for a motor vehicle may include an outer pipe through which hot gas may flow, the outer pipe extending along a longitudinal direction, defining an outer pipe interior, and including two outer pipe walls in a cross section perpendicular to the longitudinal direction. The heat exchanger may also include an inner pipe arranged in the outer pipe interior, the inner pipe extending along the longitudinal direction, being closed on a first longitudinal end, defining an inner pipe interior, and including two inner pipe walls in the cross section. The inner pipe walls may include a plurality of apertures by which the inner and outer pipe interiors may communicate fluidically. The heat exchanger may further have a plurality of thermoelectric modules arranged on an outer side of the outer pipe walls, each having a hot side facing the outer pipe and a cold side facing away from the outer pipe, and at least one coolant pipe through which a coolant may flow and which is arranged on the cold side of at least one thermoelectric module.

### CROSS-REFERENCE TO RELATED APPLICATIONS

This application claims priority to German Patent Application No. DE 10 2017 210 271.3, filed on Jun. 20, 2017, German Patent Application No. DE 20 2016 008 276.1, filed on Nov. 29, 2016, and German Patent Application No. DE 20 2016 008 278.8, filed on Nov. 29, 2016, the contents of all of which are incorporated herein by reference in their entireties.

### TECHNICAL FIELD

The invention relates to a heat exchanger, in particular an exhaust gas heat exchanger, for a motor vehicle. The invention further relates to a motor vehicle comprising an internal combustion engine, comprising an exhaust gas system and such a heat exchanger, which cooperates with the exhaust gas system.

### BACKGROUND

Heat exchangers are used in connection with exhaust gas systems of internal combustion engines, in order to harness the heat contained in the exhaust gas. For this purpose, thermoelectric modules can be provided with thermoelectric elements in the heat exchanger. Such thermoelectric elements consist of thermoelectric semiconductor materials, which convert a temperature difference into a potential difference, thus into an electric voltage, and vice versa. The heat exchanger can convert thermal energy into electrical energy in this way. Physically, the thermoelectric modules are based on the Seebeck effect, when they convert heat into electrical energy. Inside a thermoelectric module, p-doped and n-doped thermoelectric elements are interconnected. Typically, a plurality of such thermoelectric modules is interconnected to a thermoelectric generator, which can generate electrical energy or an electric voltage, respectively, from a temperature difference in connection with a corresponding heat flow. The temperature difference between the hot sides and the cold sides of the thermoelectric modules required for generating electrical energy is generated in the heat exchanger, in that the hot gas is brought into thermal interaction with the hot sides and a coolant is brought into thermal interaction with the cold sides of the thermoelectric modules with temperatures, which are lower as compared to the hot gas. This is successful in that the hot and cold sides of the thermoelectric modules are suitably arranged in the heat exchanger, through which the hot gas and the coolant flows.

### SUMMARY

The invention at hand deals with the problem of specifying an improved or at least a different embodiment, which is characterized by an improved efficiency, for a heat exchanger of the above-described type.

This object is solved by means of the subject matter of the independent patent claims. Preferred embodiments are the subject matter of the dependent patent claims.

It is thus the general idea of the invention to arrange thermoelectric modules comprising thermoelectric elements in a heat exchanger in such a way that the hot gas guided through the heat exchanger impacts the hot sides of the thermoelectric modules in the form of an impact jet. As a result, a particularly large amount of heat is extracted from the hot gas, which can be converted into electrical energy by the thermoelectric modules, following the operating principle of a thermoelectric generator. An improved efficiency of the heat exchanger is associated therewith, which proves to be advantageous in particular when said heat exchanger is operated as exhaust gas heat exchanger, in order to harness the energy contained in the exhaust gas of an internal combustion engine.

A heat exchanger according to the invention, which can preferably be used as exhaust gas heat exchanger, comprises an outer pipe for hot gas to flow through, which extends along a longitudinal direction and which defines an outer pipe interior and which, for this purpose, comprises two outer pipe pipe walls in a cross section perpendicular to the longitudinal direction. An inner pipe for the hot gas to flow through, which extends along the longitudinal direction and which defines an inner pipe interior, is arranged in the outer pipe interior, preferably coaxially to the outer pipe. The inner pipe is embodied so as to be closed on a longitudinal end and comprises at least two inner pipe pipe walls in the cross section perpendicular to the longitudinal direction. A plurality of apertures, which is present in the inner pipe pipe walls, is significant for the invention. The inner pipe interior communicates fluidically with the outer pipe interior by means of said apertures. The heat exchanger according to the invention furthermore comprises a plurality of thermoelectric modules, which are arranged on an outer side of the outer pipe pipe walls. The thermoelectric modules in each case have a hot side, which faces the outer pipe, and a cold side, which faces away from the outer pipe. The heat exchanger furthermore comprises at least one coolant pipe for a coolant to flow through, which is arranged on the cold side of at least one thermoelectric module.

By means of the above-described embodiment or arrangement according to the invention, respectively, of outer pipe and inner pipe, as well as the outer pipe or inner pipe pipe walls, respectively, with a cross section perpendicular to the longitudinal direction, it is attained that the hot gas, which flows through the inner pipe, can only reach into the outer pipe in a direction at right angles to the longitudinal direction through the apertures, which are present in the inner pipe pipe walls, and impacts the outer pipe pipe walls there. An advantageous, high dynamic pressure is thereby generated in the interior in the hot gas. As a result, a high impact effect of the hot gas is attained, when, after passing through the apertures, the hot gas impacts the outer pipe pipe walls of the outer pipe, on which the hot sides of the thermoelectric modules are arranged on the outer side. The desired, improved thermal interaction of the hot gas with the thermoelectric modules is attained in this way, so that a particularly large amount of heat is extracted from the hot gas. As a result, the thermoelectric modules, which act as thermoelectric generators, generate correspondingly more electrical energy, which, in turn, increases the efficiency of the heat exchanger.

According to a preferred embodiment, the plurality of apertures is arranged in a grid-like manner by forming at least two grid lines and at least two grid columns in the at least one inner pipe pipe wall. An advantageous, even distribution of the hot gas to the hot sides of the individual thermoelectric modules can be attained in this way.

In the case of an advantageous further development, at least two grid lines and/or at least two grid columns can have a different number of apertures. These measures mean the realization of locally different opening structures in the inner pipe pipe wall, whereby a locally different distribution of the hot gas is attained. The attained heat transfer can thus be adapted to local flow situations of the hot gas in the inner pipe interior in an advantageous manner.

In the case of another advantageous further development, the apertures of at least two adjacent grid columns and/or of at least two adjacent grid lines are arranged offset to one another.

According to another preferred embodiment, at least one aperture has a nozzle-like geometry. The hot gas in the respective aperture is accelerated additionally by means of such a nozzle-like geometry, so that an impact jet comprising an increased pulse is created.

According to another preferred embodiment, at least one aperture has a slit-like geometry. Experimental studies have shown that an impact jet, which provides for a particularly effective heat transfer, is created in this way.

Advantageously, a slit length, which is measured along the longitudinal slit direction, of at least one aperture can be at least five times, preferably at least ten times, a slit width, which is measured at right angles to the longitudinal slit direction.

In the case of an advantageous further development, the slit length of at least one aperture is between 1 mm and 30 mm. In the alternative or in addition, a slit width of at least one aperture, which is measured at right angles to the slit length, can be between 0.2 mm and 2 mm.

Preferably, the value of the slit length is at least five times, particularly preferably at least ten times, the slit width.

In the case of an advantageous further development, at least two apertures have a different slit length. In the alternative or in addition, at least two apertures extend along different directions of extension in the case of this further development.

According to a further preferred embodiment, at least one aperture has a round, preferably a circular or elliptical, or polygonal or star-shaped geometry. Experimental studies have shown that such a round or polygonal, respectively, or star-shaped geometry of the respective aperture creates an impact jet, which provides for a particularly efficient heat transfer to the thermoelectric modules.

On at least one aperture, an opening collar is embodied, which encloses said aperture and which protrudes towards the outer pipe according to another preferred embodiment. The impact jet, which flows through the aperture, can be directed accurately at a certain area of the outer pipe pipe wall with the help of such an opening collar. It is thus possible to ensure that the impact jet impacts an area of the outer pipe pipe wall, at which a thermoelectric module is arranged as well.

Particularly preferably, at least one aperture tapers away from the inner pipe interior towards the outer pipe interior, or, in the alternative, from the outer pipe interior to the inner pipe interior, preferably conically.

Particularly preferably, at least one aperture extends along a direction of extension, which forms a right angle or an acute angle with an outer side of the inner pipe pipe wall. This allows for an inclined arrangement of the respective aperture away from the inner pipe pipe wall, so that the impact jet can be directed in a well-aimed manner at an area of the outer pipe, in which a thermoelectric module for accommodating thermal energy from the impact jet is arranged as well.

In the case of an advantageous further development, at least one aperture has a preferably completely circumferential, beveled or conical or convex opening edge towards the inner pipe interior. Such an embodiment reduces the swirling of the fluid, which flows through, which increases the pressure losses of the heat exchanger on the hot gas side and thus the efficiency of the heat exchanger.

According to another preferred embodiment, the at least one inner pipe pipe wall has at least one elevation, which points away from the inner pipe interior and in which at least two apertures are arranged, wherein the two apertures are arranged at an acute angle to one another. This provides for the arrangement of a plurality of impact jet openings at a concentric position, which is associated with production-related and structural freedoms favorable forming parts or installation space-optimized inner pipes.

The invention also relates to a heat exchanger arrangement comprising at least two heat exchangers, which are arranged on top of one another and which can preferably be stacked on top of one another. The heat exchangers of the heat exchanger arrangement communicate fluidically with one another via a common gas outlet. The above-described advantages of the heat exchanger can thus also be transferred to the heat exchanger arrangement according to the invention.

The invention further relates to a motor vehicle comprising an internal combustion engine comprising an exhaust gas system and an above-presented heat exchanger according to the invention. The above-described advantages of the heat exchanger can thus also be transferred to the motor vehicle according to the invention.

Further important features and advantages of the invention follow from the subclaims, from the drawings, and from the corresponding figure description by means of the drawings.

It goes without saying that the above-mentioned features and the features, which will be described below, cannot only be used in the respective specified combination, but also in other combinations or alone, without leaving the scope of the invention at hand.

Preferred exemplary embodiments of the invention are illustrated in the drawings and will be described in more detail in the description below, whereby identical reference numerals refer to identical or similar or functionally identical components.

### BRIEF DESCRIPTION OF THE DRAWINGS

In each case schematically:

FIG. 1 shows an example of a heat exchanger embodied as exhaust gas heat exchanger in a longitudinal section,

FIG. 2 shows the heat exchanger of FIG. 1 in a cross section perpendicular to the longitudinal direction of the heat exchanger,

FIG. 3 shows a section through a U-shaped coolant pipe of the heat exchanger,

FIG. 4 shows an alternative of the heat exchanger according to FIGS. 1 and 2, in the case of which the coolant pipes do not extend in the longitudinal direction, as in the case of the example of FIG. 1, but at right angles thereto,

FIGS. 5-23 show different embodiment options of the individual apertures.

### DETAILED DESCRIPTION

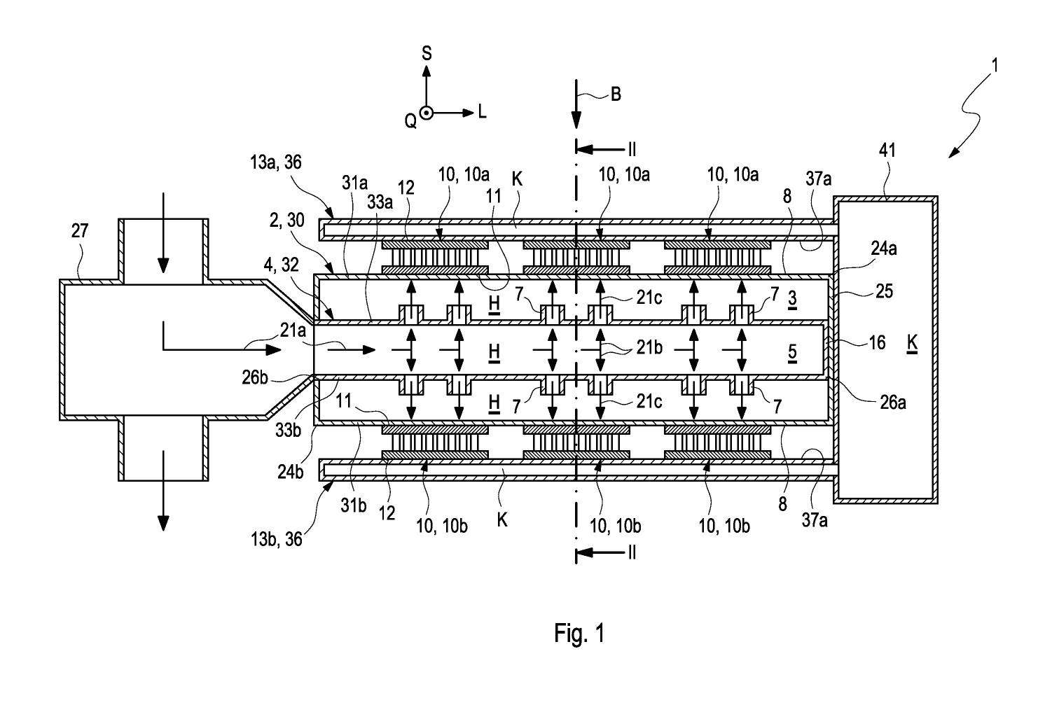

FIG. 1 shows an example of a heat exchanger 1, which is embodied as exhaust gas heat exchanger, in a schematic view. According to FIG. 1, the heat exchanger 1 has an outer pipe 2 for a hot gas H to flow through, which extends along a longitudinal direction L and which defines an outer pipe interior 3. An inner pipe 4, through which the hot gas H can likewise flow, and which defines an inner pipe interior 5, is arranged in the outer pipe interior 3.

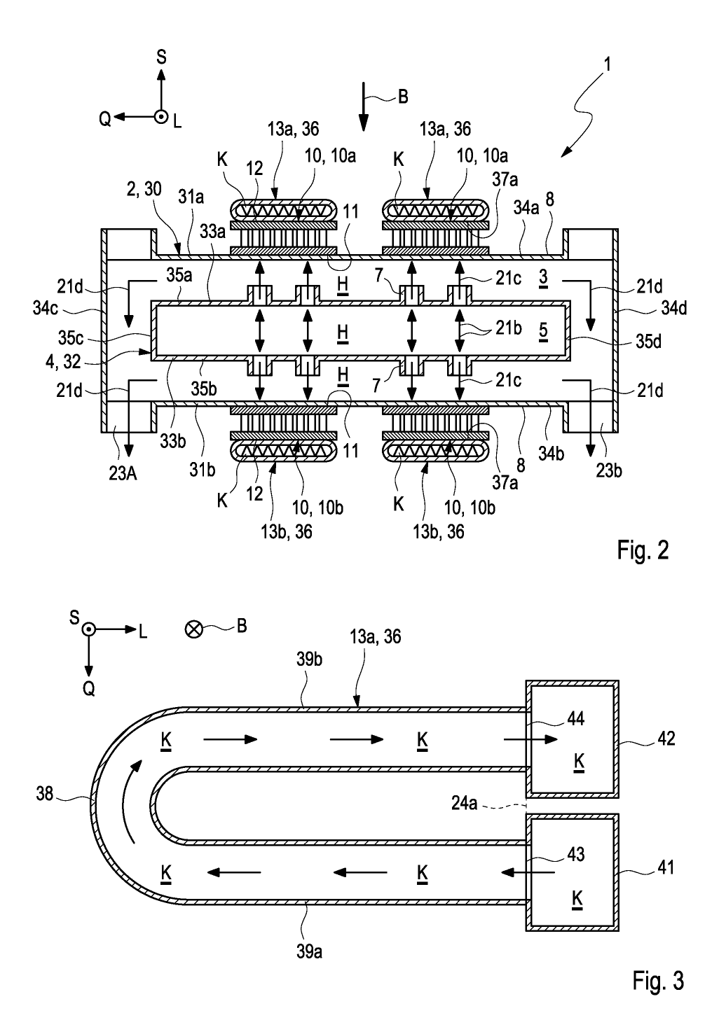

The outer pipe 2 is embodied as flat pipe 30 comprising a first outer pipe pipe wall 31a and a second outer pipe pipe wall 31b, which is located opposite the first outer pipe pipe wall 31a. According to FIGS. 1 and 2, a portion of the thermoelectric modules 10—hereinafter referred to as first thermoelectric elements 10a—are arranged on the first outer pipe pipe wall 31a. The remaining thermoelectric elements 10—hereinafter referred to as second thermoelectric elements 10b—are arranged on the second outer pipe pipe wall 31b. In the example scenario, the inner pipe 4 is also embodied as flat pipe 32 comprising a first inner pipe pipe wall 33a and a second inner pipe pipe wall 33b located opposite the first inner pipe pipe wall 33a.

FIG. 2 shows the heat exchanger 1 from FIG. 1 in a cross section perpendicular to the longitudinal direction L along the sectional line II-II of FIG. 1. It can be seen that in the cross section perpendicular to the longitudinal direction L, the two outer pipe pipe walls 31a, 31b in each case form a broad side 34a, 34b of the outer pipe 2, which is realized as flat pipe 30. The flat pipe 30, which forms the outer pipe 2, furthermore has two narrow sides 34c, 34d in the cross section perpendicular to the longitudinal direction L. The side ratio of one of the two broad sides 34a, 34b to one of the two narrow sides 34c, 34d is more than 1, preferably at least 2, maximally preferably at least 4.

In the cross section perpendicular to the longitudinal direction L, the two inner pipe pipe walls 33a, 33b in each case form a broad side 35a, 35b of the inner pipe 4, which is realized as flat pipe 32. In the cross section perpendicular to the longitudinal direction L, the flat pipe 32, which forms the inner pipe 4, furthermore has two narrow sides 35c, 35d. The side ratio of one of the two broad sides 35a, 35b to one of the two narrow sides 35c, 35d is more than 1, preferably at least 2, maximally preferably at least 6.

According to FIG. 2, the first outer pipe pipe wall 31a faces the first inner pipe pipe wall 33a in the cross section perpendicular to the longitudinal direction L. Accordingly, the second outer pipe pipe wall 31b faces the second inner pipe pipe wall 33b.

In the example of FIGS. 1 and 2, the heat exchanger 1 furthermore comprises a first coolant pipe 13a and a second coolant pipe 13b for a coolant K to flow through, which has a lower temperature than the hot gas H. The coolant pipes 13a, 13b are thus arranged on the cold sides 12 of the thermoelectric modules 10, so that the coolant K, which flows through the coolant pipes 13, can thermally couple to the cold sides 12 of the thermoelectric modules 10.

The first coolant pipe 13a is arranged on the cold sides 12 of the first thermoelectric modules 10a. The second coolant pipe 13b is arranged on the cold sides 12 of the second thermoelectric modules 10b. The outer pipe 2 is thereby arranged between the first and the second coolant pipe 13a, 13b along a stack direction S, which runs at right angles to the longitudinal direction L of the outer pipe 2. The installation space required for the heat exchanger 1 in the stack direction S can be kept small in this way. The coolant pipes 13a, 13b can in each case also be embodied as flat pipe 36, the broad sides 37a of which face the first or second thermoelectric modules 10a, 10b, respectively, in the cross section perpendicular to the longitudinal direction L.

On a first longitudinal end 26a, the inner pipe 4 is embodied so as to be closed. For this purpose, the inner pipe has a front wall 16. On a second longitudinal end 26b of the inner pipe 4, which is located opposite the first longitudinal end 26a, however, a gas inlet 27 for introducing the hot gas H into the inner pipe 4 connects to the inner pipe 4. In other words, the inner pipe 4 is embodied so as to be open on the second longitudinal end 26b. In the first inner wall pipe wall 33a and in the second inner wall pipe wall 33b of the inner pipe 4, a plurality of apertures 7 is embodied in each case, by means of which the inner pipe interior 5 communicates fluidically with the outer pipe interior 3. The hot gas H, which flows through the outer pipe 2, can be thermally coupled to the hot sides 11 of the thermoelectric modules 10 in this way.

FIG. 3 shows a top view onto the coolant pipe 13a in a viewing direction B, which is suggested by means of an arrow in FIG. 1, which extends perpendicular to the longitudinal direction L and which runs opposite to the stack direction S. In the example of FIG. 3, the first coolant pipe 13a has a U-shaped geometry comprising a base 38 and a first and a second leg 39a, 39b. The two legs 39a, 39b extend along the longitudinal direction L of the outer pipe 2. On a first longitudinal end 24a (see FIG. 1) of the outer pipe 2, a coolant distributor 41 is present, which communicates fluidically with a coolant inlet 43 of the first coolant pipe 13, which is present on the first leg 39a. A coolant collector 42, which fluidically communicates with a coolant outlet 44 of the first coolant pipe 13a, which is present on the second leg 39b, is likewise present on the first longitudinal end 24a of the outer pipe 2. The two coolant pipes 13a, 13b can be embodied as identical parts. In this case, the second coolant pipe 13b is likewise embodied as shown in FIG. 3.

The flow-through of the heat exchanger 1 with hot gas H will be described below by means of FIG. 1. Via the gas inlet 27, the hot gas H is introduced into the inner pipe interior 5, which is defined by the inner pipe 4, and flows through said inner pipe interior along the longitudinal direction L (see arrows 21a). Due to the fact that the inner pipe interior 5 is defined by the front wall 16 of the inner pipe 4 in the longitudinal direction L, the hot gas H can only leave the inner pipe interior 5 along the stack direction S, thus at right angles to the longitudinal direction L, through the apertures 7, which are embodied in the first or second inner pipe pipe wall 33a, 33b, respectively (see arrows 21b). Due to the dynamic pressure, which forms in the inner pipe interior 5 in the hot gas H, the hot gas H is accelerated while flowing through the apertures 7 and in each case impacts the first or second outer pipe pipe wall 31a, 31b, respectively, of the outer pipe 2, in the form of an impact jet (see arrows 21c). Thermal energy is thereby emitted to the thermoelectric modules 10. The hot gas H, which bounces off the outer pipe pipe walls 31a, 31b, thus reflected hot gas, can leave the heat exchanger 1 (see arrows 21d) through two gas outlets 23a, 23b (see FIG. 2), which are present on the outer pipe 2 and which extend along the stack direction S. In the scenario of FIGS. 1 and 2, the outer pipe 2 is embodied so as to be closed on one of the two longitudinal ends 24a, 24b, which are located opposite one another along the longitudinal direction. The outer pipe 2 is thereby closed by means of a front wall 25. This allows for an advantageous discharge of the hot gas H in the outer pipe 2 in two directions opposite one another (see arrows 21d in FIG. 2), which is known to the pertinent person of skill in the art as “medium crossflow”.

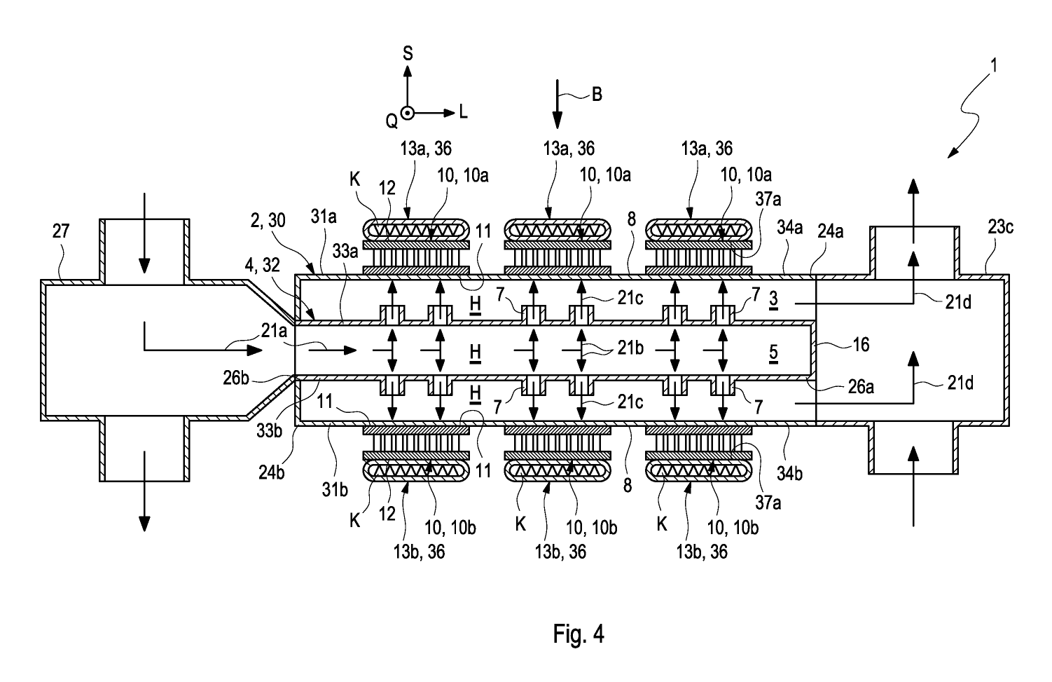

FIG. 4 illustrates an alternative of the example of FIG. 1, in the case of which the outer pipe 2 is embodied so as to be open on the longitudinal end 24a for discharging the hot gas H. This allows for an advantageous discharge of the hot gas H in only one direction (see arrows 21d in FIG. 4) via a gas outlet 23c, which connects to the outer pipe 2 on the first longitudinal end 24a. This scenario is known to the pertinent person of skill in the art as “maximum crossflow”. In an alternative, which is not shown in detail in the figures, the alternatives “maximum crossflow” and “medium crossflow” can also be combined.

The heat exchanger 1 according to FIG. 4 has three first coolant pipes 13a and three second coolant pipes 13b. In alternatives, the number of first and second coolant pipes 13a, 13b can vary. According to FIG. 4, the first and second coolant pipes 13a, 13b are in each case arranged at a distance to one another along the longitudinal direction L and in each case extend along a transverse direction Q, which runs perpendicular to the longitudinal direction L as well as to the stack direction S.

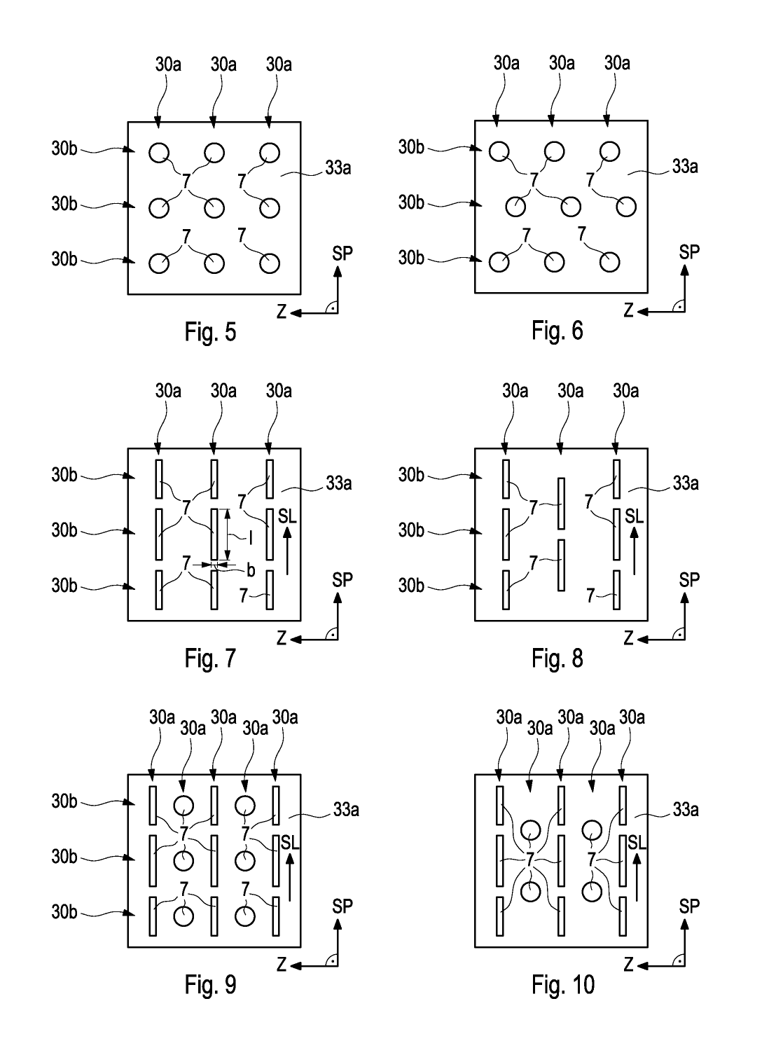

FIGS. 5 to 18 show different embodiment options of the individual apertures 7 in the inner pipe outer wall 33a. For the sake of simplicity, FIGS. 5 to 18 thereby in each case show only a section of the inner pipe outer wall 33a. The examples of FIGS. 5 to 13 can be combined with one another, where appropriate. FIGS. 5 to 13 in each case illustrate the inner pipe outer wall 33a in an exemplary manner. It goes without saying that the embodiments shown in FIGS. 5 to 18 can also be realized in the inner pipe outer wall 33b.

In the examples of FIGS. 5 to 10, the apertures 7 are arranged in the inner pipe pipe wall 33a in a grid-like manner by forming a plurality of grid lines 30b and a plurality of grid columns 30a. In the example of FIGS. 5 to 10, the apertures 7 extend in a respective grid column 30a along a column direction SP. The apertures 7 of a respective grid line 30b thus extend along a line direction Z. In the example scenario, the column direction SP and the line direction Z run orthogonally to one another.

In the example of FIG. 6, the apertures 7 of adjacent grid lines 30b are in each case arranged offset to one another in the line direction Z. In contrast, provision is not made in the example of FIG. 5 for such an offset arrangement of the apertures 7. In the example of FIGS. 5 and 6, the individual apertures 7 in each case have a circular geometry in the top view onto the inner pipe outer wall 33a. However, other round geometries, in particular an elliptical geometry (not shown in the Figures) are also conceivable.

As revealed by the illustration of FIG. 13, the apertures 7 can also have a non-round geometry. FIG. 13 thus in each case shows an aperture 7 in an exemplary manner with the geometry of a triangle, quadrangle, pentagon and hexagon, thus of a polygon. A star-shaped geometry is also possible, as is also shown in FIG. 13 for illustration purposes.

In the example of FIGS. 7 and 8, the individual apertures 7 in each case have a slit-like geometry. The apertures 7, which are embodied in a slit-like manner, in each case extend along a longitudinal slit direction SL. In the example of the Figures, the longitudinal slit direction SL and the gap direction SP are identical. A slit length 1, which is measured along the longitudinal slit direction SL, of at least one aperture 7 can be at least five times, preferably at least ten times, a slit width b, which is measured at right angles to the longitudinal slit direction SL.

Particularly advantageously, the slit length 1 of the apertures 7 with slit-like geometry is between 1 mm and 30 mm. The slit width b of the apertures 7 can be between 0.2 mm and 2 mm. The value of the slit length 1 is preferably at least five times, particularly preferably at least ten times, the slit width b.

In non-illustrated alternatives of the example, the individual apertures 7 with slit-like geometry can also have different slit lengths. Analogously to FIGS. 5 and 6 with circular embodiment of the apertures 7, the apertures 7 of adjacent grid columns 30a are in each case arranged offset to one another along the gap direction SP in the example of FIG. 8. In contrast, such an offset arrangement of the apertures 7 is not realized in the example of FIG. 7.

FIGS. 9 and 10 illustrate that apertures 7 with different geometry can also be combined with one another. In the example of FIGS. 9 and 10, provision is made for apertures 7 with circular as well as slit-shaped geometry in an exemplary manner. In the example of FIGS. 9 and 10, grid columns 30a, in which the apertures 7 have a slit-shaped geometry, alternate with grid columns 30a, in the case of which the apertures 7 have a circular geometry, along the line direction Z. It goes without saying that other geometries can also be combined with one another. In the case of the apertures 7, a variation of their geometry with regard to the grid lines 30b is possible as well. Moreover, more than two different geometries can also be provided and combined with one another.

Analogously to FIGS. 5 and 6 with circular embodiment of the apertures 7, the apertures 7 of adjacent grid columns 30a are in each case arranged offset to one another along the gap direction SP in the example of FIG. 10. In the example of FIG. 10, the apertures 7 with circular geometry are thus arranged offset to the apertures 7 with slit-shaped geometry along the gap direction SP. In contrast, no such offset arrangement of the apertures 7 is realized in the example of FIG. 9.

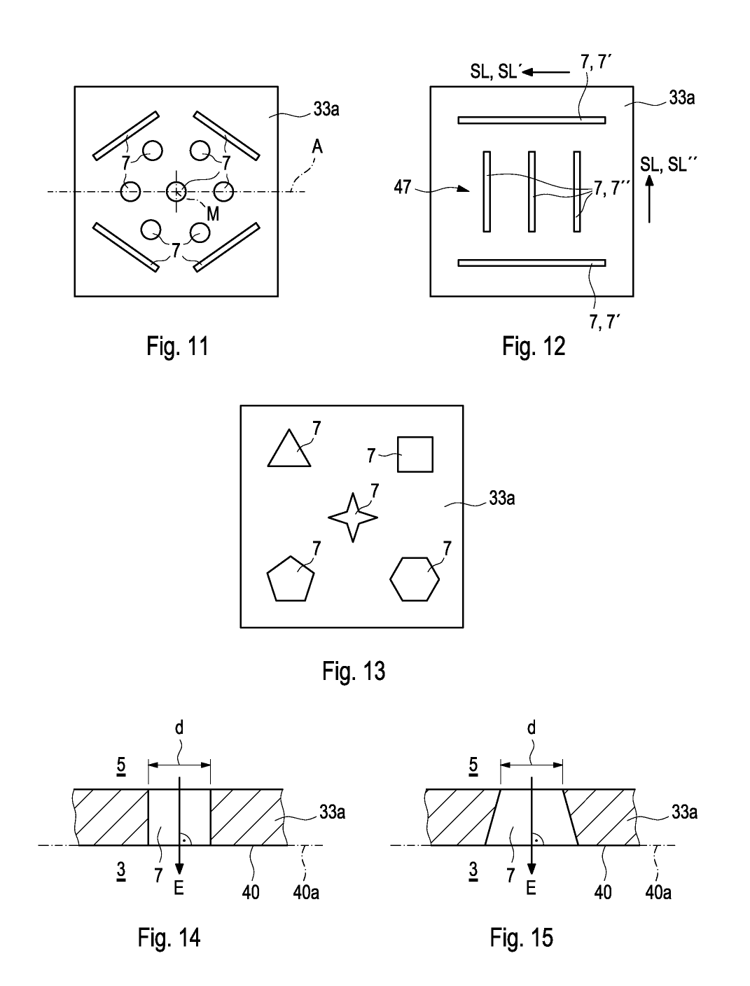

An axially symmetrically arrangement of the apertures 7 is shown in the example of FIG. 11. In this example, an aperture 7 with circular geometry forms the center point M of a hexagon, in the corners of which an aperture 7 with a circular geometry is arranged as well. In addition, provision is made radially outside of said hexagon for four additional slit-shaped apertures 7 in an exemplary manner. The slit-shaped apertures 7 as well as the apertures 7 with circular geometry are arranged axially symmetrical to an axis of symmetry A. The position of the axis of symmetry A is defined by a virtual connecting line of three adjacent apertures 7 with circular geometry.

FIG. 12 shows a further example for apertures 7 with slit-shaped geometry. In the example of FIG. 12, not all apertures 7 extend along the same longitudinal slit direction SL. In fact, the longitudinal slit direction SL can vary for individual apertures 7. In the example of FIG. 12, two apertures 7, which are additionally identified with 7′ in FIG. 12, extend at a distance from one another along the same slit direction, which is identified with SL′ in FIG. 12, in an exemplary manner. 3 further apertures 7, which are additionally identified with 7″, are arranged spaced apart from one another in a space 47 between the two apertures 7′. The longitudinal slit direction SL of these apertures 7″, which is additionally identified with SL″ in FIG. 12, runs perpendicular to the longitudinal slit direction SL′ of the two apertures 7. It goes without saying that a variety of further developments and variations of the example of FIG. 12 are conceivable in further options.

FIGS. 14 to 23 show further exemplary embodiments, by means of which possible embodiments of the apertures 7 are to be clarified. The examples of FIGS. 14 to 23 can be combined with one another, where appropriate. The examples of FIGS. 5 to 13 can also be combined with the examples of FIGS. 14 to 23, where appropriate. FIGS. 14 to 22 in each case show an individual aperture 7, which is embodied in the inner pipe pipe wall 33a, in a longitudinal section perpendicular to the outer side 40 of the inner pipe pipe wall 33a.

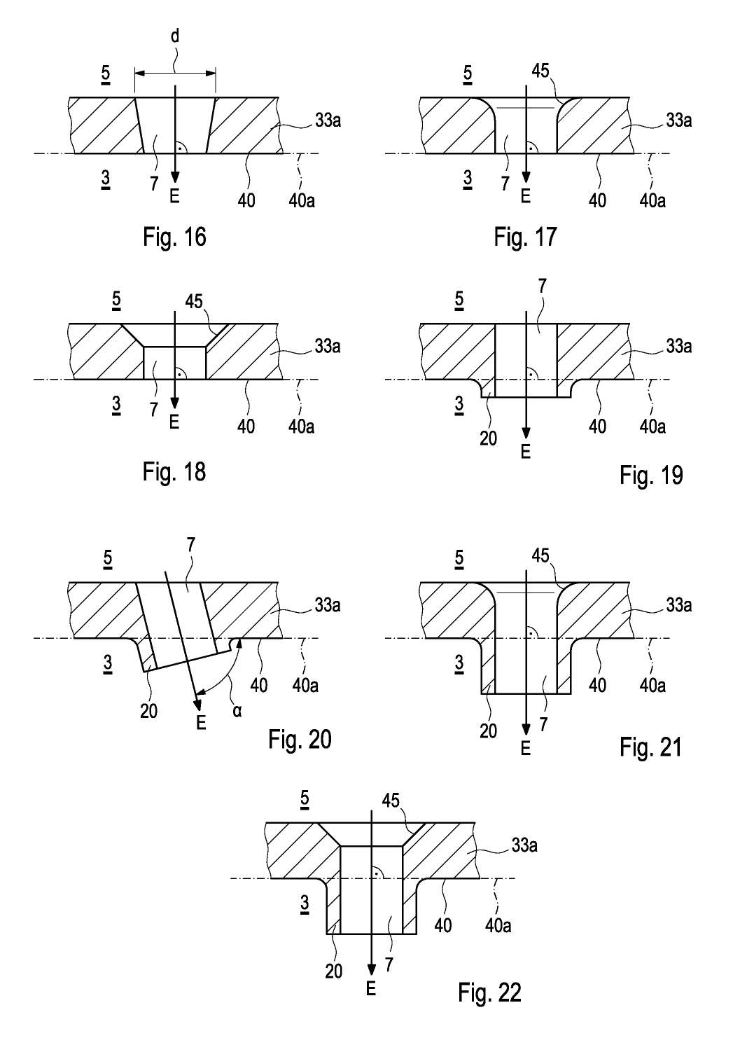

The apertures 7 extend along a direction of extension E. In the example of FIGS. 14 to 19, 21, 22, the direction of extension E extends perpendicular to a plane 40a, which is defined by the outer side 40 of the inner pipe pipe wall 33a in the area of the aperture 7. In the example of FIG. 14, the aperture 7 has a constant opening diameter d along the direction of extension E or a constant slit width b, respectively. Analogously, a described opening diameter d in the further descriptions of the examples of FIGS. 14 to 23 is alternatively synonymous with a slit width b in the case of a slit-shaped geometry of the apertures 7, even if this is not mentioned expressly. In the example of FIG. 15, the aperture 7 tapers conically from the outer pipe interior 3 to the inner pipe pipe interior 5, i.e. the opening diameter d decreases from the outside to the inside. In the example of FIG. 16, the aperture 7 tapers conically from the inner pipe interior 5 to the outer pipe interior 3, i.e. the opening diameter d decreases from the inside to the outside. A combination of the examples of FIGS. 15 and 16 is conceivable as well, so that a local constriction (not shown) of the opening diameter d along the direction of extension E follows. The aperture 7 has the geometry of a nozzle in this case.

In the example of FIG. 18, the aperture 7 has a beveled or conical opening edge 45 towards the inner pipe interior 5. Preferably, the beveled or conical opening edge 45, respectively, circulates completely. In the example of FIG. 17, the aperture 7 has an opening edge 45 towards the inner pipe interior 5 with a contour path, which is convex in the longitudinal section. Preferably, the beveled or conical opening edge 45, respectively, circulates completely. In the alternative or in addition and in a different, i.e., changing design, such a functional design of the opening edge 45 can analogously also be used on the opening edge, which faces the outer pipe interior 3 (not shown). In special combinations, the aperture 7 receives the geometry of a nozzle.

On the aperture 7, an opening collar 20, which encloses said aperture 7 and which protrudes towards the outer pipe 2 (see FIG. 1), is embodied in the examples of FIGS. 19 to 22. The opening collar 20 is thus arranged on the outer side 40 and protrudes outwards from said outer side, thus away from the inner pipe pipe wall 33a.

In the example of FIG. 19, the direction of extension E of the aperture 7 runs perpendicular to the plane 40a, which is defined by the outer side 40 of the inner pipe pipe wall 33a. The opening collar 20 thus also protrudes orthogonally outwards from the inner pipe pipe wall 33a.

In the example of FIG. 20, the direction of extension E of the aperture 7 forms an acute angle α with the plane 40a of the outer side 40. The opening collar 20 thus also protrudes outwards from the inner pipe pipe wall 33a at an acute angle α.

FIG. 21 shows a combination of the examples of FIGS. 17 and 19 in an exemplary manner. FIG. 22 shows a combination of the examples of FIGS. 18 and 19 in an exemplary manner. It goes without saying that further combinations of the examples of FIGS. 14 to 22 are conceivable, where appropriate.

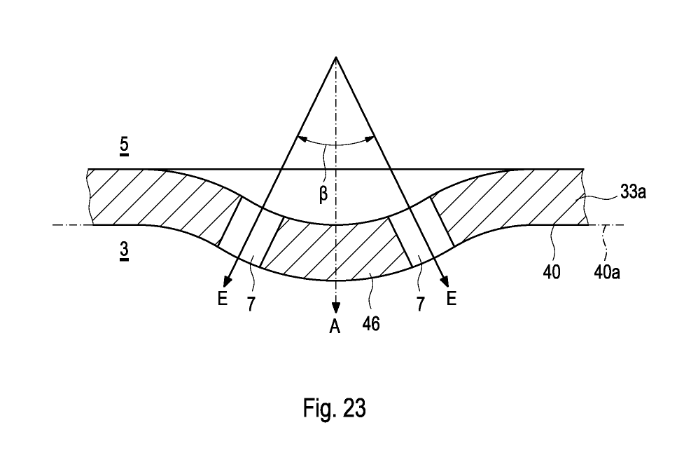

FIG. 23 shows a further alternative, in the case of which the inner pipe inner wall 33a has at least one elevation 46, which points away from the inner pipe interior 5 and in which two or more apertures 7 are arranged. As illustrated in FIG. 23, the two apertures are preferably arranged at an acute angle β to one another. The two apertures 7 can also be arranged axially symmetrical to an axis of symmetry A, which runs perpendicular to the plane 40a in the longitudinal section of FIG. 23.
A heat exchanger arrangement comprising two heat exchangers 1, which are arranged on top of one another, can be formed from the above-described heat exchanger 1. The heat exchangers 1 can preferably be stacked on top of one another along the stack direction S (see FIG. 2) and can communicate with one another fluidically by means of the two gas outlets 23a, 23b. FIG. 2 thus shows a single heat exchanger 1 of such a heat exchanger arrangement

1. A heat exchanger for a motor vehicle, comprising:
an outer pipe through which hot gas is flowable, the outer pipe extending along a longitudinal direction, defining an outer pipe interior, and including at least two outer pipe walls in a cross section perpendicular to the longitudinal direction;
an inner pipe arranged in the outer pipe interior, the inner pipe extending along the longitudinal direction, being closed on a first longitudinal end, defining an inner pipe interior, and including at least two inner pipe walls in the cross section perpendicular to the longitudinal direction;
a plurality of apertures in at least one inner pipe wall by which the inner pipe interior communicates fluidically with the outer pipe interior;
a plurality of thermoelectric modules arranged on an outer side of the outer pipe walls, each thermoelectric module having a hot side, which faces the outer pipe, and a cold side, which faces away from the outer pipe; and
at least one coolant pipe through which a coolant is flowable and which is arranged on the cold side of at least one thermoelectric module.

2. The heat exchanger according to claim 1, wherein the plurality of apertures is arranged in a grid-like manner with at least two grid lines and at least two grid columns in the at least one inner pipe wall.

3. The heat exchanger according to claim 2, wherein at least one of (i) at least two grid lines and (ii) at least two grid columns have a different number of apertures.

4. The heat exchanger according to claim 2, wherein the apertures of at least one of at least two adjacent grid columns and of at least two adjacent grid lines are arranged offset to one another.

5. The heat exchanger according to claim 1, wherein at least one aperture has a nozzle-like geometry.

6. The heat exchanger according to claim 1, wherein at least one aperture has a slit-like geometry.

7. The heat exchanger according to claim 6, wherein a slit length, which is measured along a longitudinal slit direction of the at least one aperture, is at least five times a slit width, which is measured at right angles to the longitudinal slit direction.

8. The heat exchanger according to claim 7, wherein at least one of:
the slit length is between 1 mm and 30 mm; and
the slit width is between 0.2 mm and 2 mm.

9. The heat exchanger according to claim 6, wherein at least two apertures have a different slit length.

10. The heat exchanger according to claim 1, wherein at least one aperture has one of a round, polygonal, or star-shaped geometry.

11. The heat exchanger according to claim 1, further comprising an opening collar on at least one aperture, the opening collar encloseing said at least one aperture and protrudeing towards the outer pipe.

12. The heat exchanger according to claim 1, wherein at least one aperture tapers away from the inner pipe interior towards the outer pipe interior, or from the outer pipe interior to the inner pipe interior.

13. The heat exchanger according to claim 1, wherein at least one aperture extends along a direction of extension, which forms a right angle or an acute angle with an outer side of the inner pipe wall.

14. The heat exchanger according to claim 1, wherein at least one aperture has a completely circumferential opening edge that is one of beveled, conical, or convex towards the inner pipe interior or towards the outer pipe interior.

15. The heat exchanger according to claim 1, wherein:
the at least one inner pipe wall has at least one elevation, which extends to the outside and in which at least two apertures are arranged; and
the at least two apertures are arranged at an acute angle to one another.

16. A heat exchanger arrangement comprising at least two heat exchangers arranged on top of one another, each heat exchanger including:
an outer pipe through which hot gas is flowable, the outer pipe extending along a longitudinal direction, defining an outer pipe interior, and including two outer pipe walls in a cross section perpendicular to the longitudinal direction;
an inner pipe arranged in the outer pipe interior, extending along the longitudinal direction, being closed on a first longitudinal end, defining an inner pipe interior, and including two inner pipe walls in the cross section perpendicular to the longitudinal direction;
a plurality of apertures in the inner pipe walls by which the inner pipe interior communicates fluidically with the outer pipe interior;
a plurality of thermoelectric modules arranged on an outer side of the outer pipe walls, each thermoelectric module having a hot side, which faces the outer pipe, and a cold side, which faces away from the outer pipe; and
at least one coolant pipe through which a coolant is flowable and which is arranged on the cold side of at least one thermoelectric module;
wherein the at least two heat exchangers communicate fluidically with one another via a common gas outlet for discharging the hot gas from the heat exchanger arrangement.

17. A motor vehicle comprising:
an internal combustion engine having an exhaust gas system; and
one of a heat exchanger, which cooperates with the exhaust gas system, or a heat exchanger arrangement, which cooperates with the exhaust gas system;
wherein the heat exchanger includes:
an outer pipe through which hot gas is flowable, the outer pipe extending along a longitudinal direction, defining an outer pipe interior, and including two outer pipe walls in a cross section perpendicular to the longitudinal direction;
an inner pipe arranged in the outer pipe interior, extending along the longitudinal direction, being closed on a first longitudinal end, defining an inner pipe interior, and including two inner pipe walls in the cross section perpendicular to the longitudinal direction;
a plurality of apertures in the inner pipe walls by which the inner pipe interior communicates fluidically with the outer pipe interior;
a plurality of thermoelectric modules arranged on an outer side of the outer pipe walls, each thermoelectric module having a hot side, which faces the outer pipe, and a cold side, which faces away from the outer pipe; and
at least one coolant pipe through which a coolant is flowable and which is arranged on the cold side of at least one thermoelectric module; and
wherein the heat exchanger arrangement includes at least two heat exchangers arranged on top of one another and communicating fluidically with one another via at least one common gas outlet for discharging the hot gas from the heat exchanger arrangement.

18. The heat exchanger arrangement according to claim 16, wherein the plurality of apertures is arranged in a grid-like manner with at least two grid lines and at least two grid columns in the at least one inner pipe wall.

19. The heat exchanger arrangement according to claim 18, wherein at least one of (i) at least two grid lines and (ii) at least two grid columns have a different number of apertures.

20. The heat exchanger arrangement according to claim 18, wherein the apertures of at least one of at least two adjacent grid columns and of at least two adjacent grid lines are arranged offset to one another.
